(19) United States
(12) Patent Application Publication
(10) Pub. No.: US 2009/0239339 A1
(43) Pub. Date: Sep. 24, 2009

(54) METHOD OF STACKING DIES FOR DIE STACK PACKAGE

(75) Inventors: Chung-Mao YEH, Taichung City (TW); Jack Chang, Taoyuan County (TW)

Correspondence Address: BROWDY AND NEIMARK, P.L.L.C.;624 NINTH STREET, NW, SUITE 300, WASHINGTON, DC, 20001-5303, US

(73) Assignee: LINGSEN PRECISION INDUSTRIES, LTD, Taichung (TW)

(21) Appl. No.: 12/264,653

(22) Filed: Nov. 4, 2008

(30) Foreign Application Priority Data
Mar. 18, 2008 (TW) 97109546

(51) Int. Cl. H01L 21/58

(52) U.S. Cl. 438/109; 257/E21.505

(57) ABSTRACT

A method of manufacturing a die stack package includes the steps of providing a wafer having a first surface and a second surface, said first surface having a plurality of cut ways thereon, the second surface being coated with adhesive of a predetermined thickness at a predetermined position thereof, removing parts of the adhesive by photo-lithography, each of the parts of the adhesive corresponds to the cut way and is wider than the cut way; cutting the wafer along the cut ways to make a plurality of dies, each of the dies having a part of the adhesive thereon; and stacking each of the dies, whose surface having the adhesive faces a lower-layer die, on the lower-layer die. Therefore, the method facilitates the stacking operation and saves the production cost.

### BACKGROUND OF THE INVENTION

1. Field of the Invention

The present invention relates generally to die stacks, and more particularly, to a method of stacking dies for a die stack package.

2. Description of the Related Art

Before a die is packaged, a wafer is cut into a plurality of small dies and then the dies in the desired number are taken and adhered to a proper substrate and further processed with electric connection and packaging.

A general method of stacking dies for a die stack package includes the steps of adhering a first-layer die onto the substrate, electrically connect the first-layer die with the substrate by wire bonding, and disposing adhesive on a top side of the first-layer die for adhesion with a second-layer die. Because there are wires on the first-layer die, it must be very careful to dispose the adhesive to prevent it from staining contact pads of the first-layer die. Further, before a second-layer die is stacked upon a first-layer die, a predetermined position must be reserved to avoid the wires of the first-layer die, such that the second-layer die is usually smaller than the first-layer die. In this way, there are great limitations during production of the die stack package and it is very complicated to dispose the adhesive on the second-layer or above die and to adhere the two or more dies, such that improvement is needed.

### SUMMARY OF THE INVENTION

The primary objective of the present invention is to provide a method of stacking dies for a die stack package, which simplifies the process of stacking the dies and decreases the production cost.

The foregoing objective of the present invention is attained by the method including the steps of providing a wafer having a first surface and a second surface, said first surface having a plurality of cut ways thereon, the second surface being coated with adhesive of a predetermined thickness at a predetermined position thereof; removing parts of the adhesive by photo-lithography, each of the parts of the adhesive corresponding to the cut way and being wider than the cut way; cutting the wafer along the cut ways to make a plurality of dies, each of the dies having a part of the adhesive thereon; and stacking each die, whose surface having the adhesive faces a lower-layer die, on the lowerlayer die.

In light of the above steps, each of the dies has the adhesive on the second surface thereof, and the adhesive has a predetermined thickness and is less wider than the die, such that a space is formed between the adjacent dies for receiving the wires of the next layer of the die, thus facilitating the stacking operation and saving the production cost.

### BRIEF DESCRIPTION OF THE DRAWINGS

FIG. 1 is a flow chart of a preferred embodiment of the present invention.

FIG. 2(A) is a schematic view of the preferred embodiment of the present invention in implementation.

FIG. 2(B) is another schematic view of the preferred embodiment of the present invention in implementation.

FIG. 2(C) is another schematic view of the preferred embodiment of the present invention in implementation.

FIG. 2(D) is another schematic view of the preferred embodiment of the present invention in implementation.

FIG. 2(E) is another schematic view of the preferred embodiment of the present invention in implementation.

FIG. 2(F) is another schematic view of the preferred embodiment of the present invention in implementation.

FIG. 2(G) is another schematic view of the preferred embodiment of the present invention in implementation.

### DETAILED DESCRIPTION OF PREFERRED EMBODIMENTS

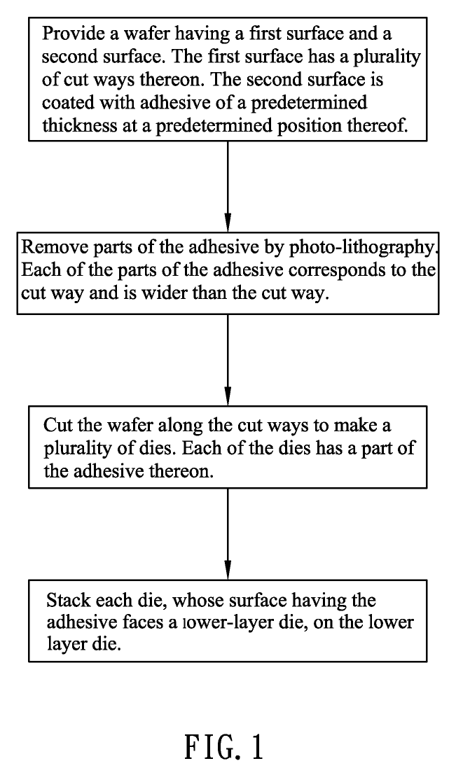

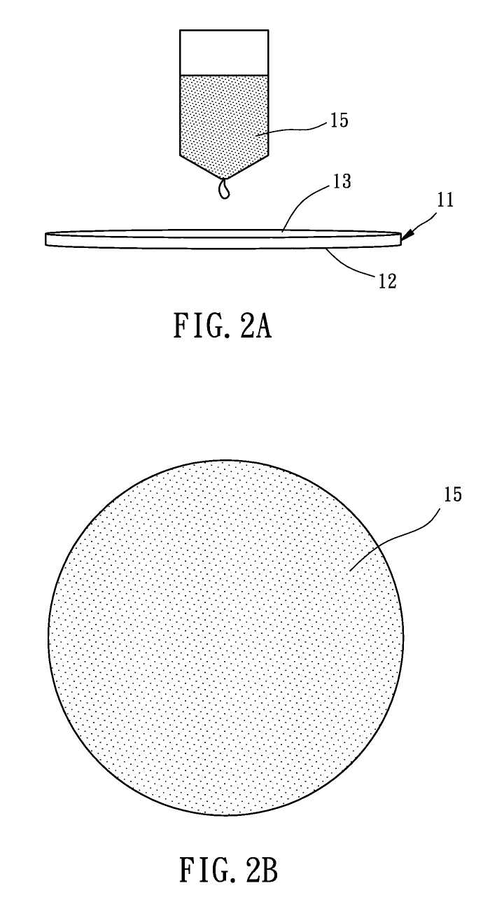

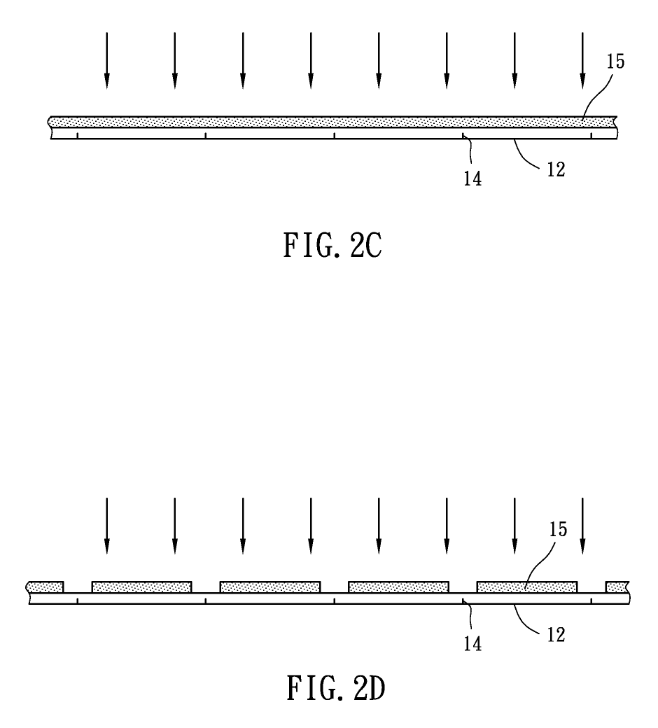

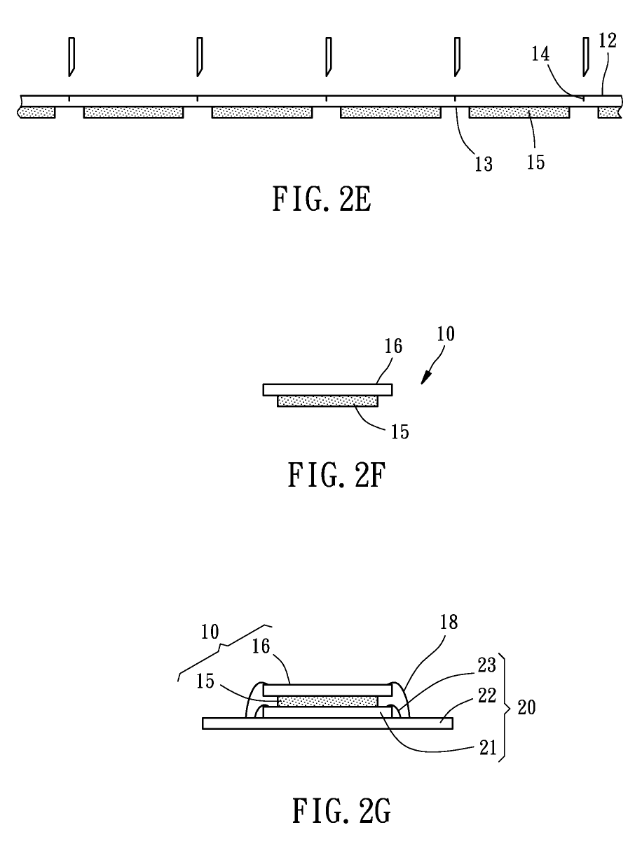

Referring to FIG. 1 and FIGS. 2(A)-2(G), a method of stacking dies for a die stack package in accordance with a preferred embodiment of the present invention includes the following steps.

(A) Provide a wafer 11. The wafer includes a first surface 12 and a second surface 13. The first surface 11 has a plurality of cut ways 14 formed thereon. The second surface 13 is eccentrically coated with adhesive 15 at a predetermined position thereof for a predetermined thickness.

(B) Remove parts of the adhesive 15 by photolithography. The parts of the adhesive 15 correspond to the cut ways 14 respectively and each are wider than the cut way 14.

(C) Cut the wafer 11 along the cut ways 14 to make a plurality of dies 16. Each of the dies 16 has a part of the adhesive 15 on the surface thereof to become a die stack 10. The adhesive 15 is C-stage adhesive, that is, hot and pressure adhesive.

(D) Stack the die stack 10, whose surface having the adhesive 15 faces a lower-layer die 21, on the lower-layer die 21.

As shown in FIG. 2(G), the die stack 10 can be stacked straight on a die unit 20 having a substrate 22, the lower-layer die 21, and a wire 23. The lower-layer die 21 is adhered to the substrate 22. The wire 23 is bonded between the lower-layer die 21 and the substrate 22. The die stack 10 is stacked on the lower-layer die 21. After pressurization and heating, the adhesive 15 is disposed on the lower-layer die 21. The thickness of the adhesive 15 enables the two dies 16 and 21 to avoid the wire 23. After the die stack 10 is adhered to the lower-layer die 21, the die stack 10 and the substrate 22 are electrically connected with each other by the wire 18.

The key point of the present invention lies in that the adhesive of a predetermined thickness is coated to the bottom side of the die stack 10 and then adhered to the lower-layer die 21 by the pressurization and heating. In addition, the arrangement of stacking the dies is not limited to two layers of the dies but includes three and more layers of the dies.

In conclusion, the present invention facilitates the adhesion of the dies while stacked on the other and reserves space for wire bonding, such that the product cost is reduced.

Although the present invention has been described with respect to a specific preferred embodiment thereof, it is no way limited to the details of the illustrated structures but changes and modifications may be made within the scope of the appended claims.

What is claimed is:

1. A method of manufacturing a die stack package, comprising steps of:
(A) providing a wafer having a first surface and a second surface, said first surface having a plurality of cut ways formed thereon, said second surface being coated with adhesive of a predetermined thickness;
(B) removing parts of said adhesive by photolithography, each of said parts of said adhesive responding to said cut way;
(C) cutting said wafer along said cut ways to make a plurality of dies, each of said dies having a part of said adhesive; and
(D) stacking each said die, whose surface having said adhesive faces a lower-layer die, on said lower-layer die.

2. The method as defined in claim 1, wherein in the step (B), each of said parts of said adhesive is wider than said cut way.

3. The method as defined in claim 1, wherein said adhesive is C-stage adhesive.

4. The method as defined in claim 1, wherein in the step (A), said adhesive is eccentrically coated on said second surface of said wafer.
